(19) United States
(12) Patent Application Publication
(10) Pub. No.: US 2005/0151265 A1
(43) Pub. Date: Jul. 14, 2005

(54) Efficient use of wafer area with device under the pad approach

(76) Inventors: Nian Yang, Mountain View, CA (US); Hiroyuki Ogawa, Sunnyvale, CA (US); Yider Wu, Campbell, CA (US); Kuo-Tung Chang, Saratoga, CA (US); Yu Sun, Saratoga, CA (US); Darlene Hamilton, San Jose, CA (US)

Correspondence Address: WAGNER, MURABITO & HAO LLP, Third Floor, Two North Market Street, San Jose, CA, 95113, US

(21) Appl. No.: 10/758,148

(22) Filed: Jan. 14, 2004

(51) Int. Cl. H01L 23/48; H01L 21/44

(52) U.S. Cl. 257/774; 257/786; 438/612

(57) ABSTRACT

More efficient use of silicon area is achieved by incorporating an active device beneath a pad area of a semiconductor structure. The pad area includes a substrate having a first metal layer above it. A second metal layer is below the first metal layer. The active device resides in the substrate below the second metal layer. A layer of dielectric separates the first and second metal layers. A via within the dielectric layer electrically couples the first and second metal layers. A via connects to the active component. Subsequent metal layers can be arranged between the first and second metal layers.

### TECHNICAL FIELD

Embodiments of the present invention relate to the field of semiconductor device design. More particularly, an embodiment of the present invention relates to a more efficient use of wafer area with a device under the pad.

### BACKGROUND

The development of semiconductor circuit design and fabrication technologies has resulted in devices such as flash memories, integrated circuits, and logic and other devices of significant complexity and density and which operate at low voltages. Due to the scaling inherent in the design of such complex, dense semiconductor chips, the efficient use of the available silicon area without compromising performance or degrading physical characteristics becomes a significant consideration.

Some chip and wafer designs incorporate a pad area. The pad is typically an area where an interface between the integrated circuit and an external circuit or system can be established. Interfaces between the chip and the external circuits and/or systems can include, for instance, bonding, probing, and packaging. To effectively establish such interfaces, the pad area is typically large, relative to the internal circuit. The pad area thus occupies a significant area of the silicon on the chip.

Taking advanced flash memory as an example, the pad area takes up more area than half of a typical memory sector comprising 512 kilobits. One typical pad size is approximately 80 micrometers by 80 micrometers, thus covering 6,400 square micrometers. Where there are several pads on a chip, such as 40 pads for the exemplary flash memory chip, the amount of silicon area covered by the pad area becomes significant. For instance, the 40 pads on the exemplary flash memory chip, each covering 6,400 square micrometers, together cover over a half million square micrometers of silicon substrate.

Conventionally, the pad area is separated from other circuits in the chip. Separating the pad and the chip internal circuits facilitates probing, bonding, and packaging, and allows the pad area to also be used for protecting the chip from the potentially harmful effects of electrostatic discharge (ESD). The pad separated from them, circuits and devices characteristic of the chip's operation are elsewhere within the chip. FIG. 1 depicts the layout of a conventional semiconductor structure 10. Pad 11 and the active devices of internal circuits 12 of semiconductor device 10 are separated.

However, as chip sizes and operating voltages are scaled down, the significance of the silicon area covered by the pad area becomes greater. The pad typically has multiple layers of metal, the top layer of which is used for the bonding, probing, and packaging. Lower layers of metal are typically used for introducing pad signals in or out between the internal circuitry of the chip and, for instance, an external system. The bottom level of metal is directly connected to the silicon substrate comprising the chip. However, no active devices are present within the substrate beneath a typical pad.

### SUMMARY

As denser, more complex chips are designed, and as operating voltages are reduced, more efficient use of silicon can become desirable. An embodiment of the present invention more efficiently uses silicon area. In one embodiment of the present invention, a semiconductor structure such as a wafer of individual dies comprising a flash or a SRAM memory, an integrated circuit, or the like incorporates an active device beneath the pad area. A component of the semiconductor structure can perform a memory function, a logic function, or another function.

A semiconductor structure having an active device below the pad area is disclosed. In one embodiment, a semiconductor structure has a pad area and has an active device disposed beneath the pad area. The active device can be, for instance, a transistor or a circuit. The active device can be one of several devices of the semiconductor structure, which can also include a non-pad area bounded at least in part by the pad area and another of the active devices disposed within the non-pad area. In one embodiment, the several devices perform a similar function.

In one embodiment, the pad area includes a substrate with a first layer of metal disposed above it and a second layer of metal disposed below the first metal layer. The active component is disposed below the second layer of metal. In one embodiment, the semiconductor structure also has a layer of dielectric disposed between the first and second metal layers and a via disposed within the dielectric layer, which electrically couples the first and second metal layers. A via connects to the active device. Subsequent layers of metal can be disposed between the first and second metal layers.

One embodiment provides a pad area apparatus for a semiconductor structure that has an active device disposed in a substrate beneath a metal layer. One embodiment provides a method for fabricating a semiconductor structure that includes a pad area that has an active device beneath the pad area.

### BRIEF DESCRIPTION OF THE DRAWINGS

The accompanying drawings, which are incorporated in and form a part of this specification, illustrate embodiments of the invention and, together with the description, serve to explain the principles of the invention. The drawings are not to scale.

FIG. 1 depicts a top view of a conventional semiconductor structure.

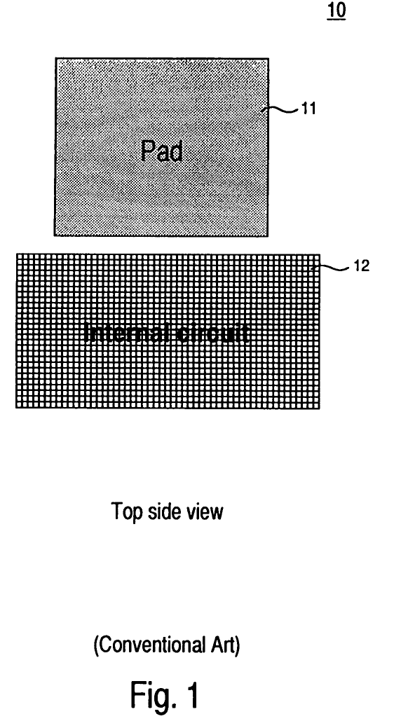

FIG. 2 depicts a cross section of a semiconductor structure having an active component under the pad area, according to one embodiment of the present invention.

FIG. 3 depicts a top view of a semiconductor structure having an active device under the pad area, according to one embodiment of the present invention.

FIG. 4 depicts a cross section of a pad area having an active device there under, according to one embodiment of the present invention.

FIG. 5 depicts a cross section of a pad area having as active devices there under two transistors, according to one embodiment of the present invention.

FIG. 6 is a flowchart of a method for fabricating a semiconductor structure, according to one embodiment of the present invention.

FIG. 7 is a flowchart of a method for fabricating a semiconductor structure, according to one embodiment of the present invention.

FIG. 8 is a flowchart of a method for fabricating a pad area, according to one embodiment of the present invention.

FIG. 9 is a flowchart of a method for fabricating a pad area, according to one embodiment of the present invention.

FIG. 10 is a flowchart of a method for fabricating a pad area, according to one embodiment of the present invention.

### DETAILED DESCRIPTION

A semiconductor structure having an active device below the pad area is disclosed. In the following detailed description of the present invention, numerous specific details are set forth in order to provide a thorough understanding of the present invention. However, it will be recognized by one skilled in the art that the present invention may be practiced without these specific details or with equivalents thereof. In other instances, well known methods, processes, procedures, components, and circuits have not been described in detail as not to unnecessarily obscure aspects of the present invention.

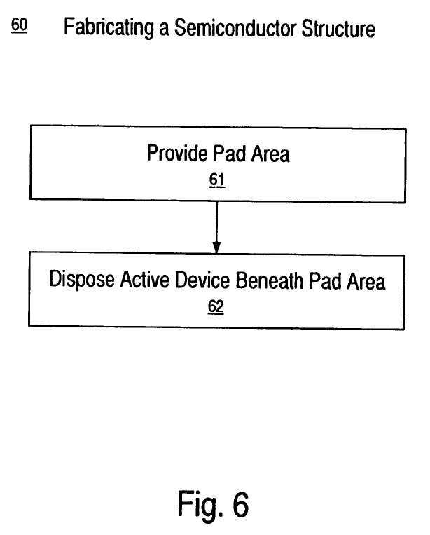

Portions of the detailed descriptions of embodiments of the invention that follow are presented and discussed in terms of processes. Although specific steps and sequence thereof are disclosed in figures herein (e.g., FIGS. 6-10) describing the operations of these processes (e.g., processes 60, 70, 80, 90, and 100), such steps and sequence are exemplary. Embodiments of the present invention are well suited to performing various other steps or variations of the steps recited in the flowcharts of the figures herein, and in another sequence than the sequence depicted and described.

The present invention is discussed primarily in the context of a semiconductor structure having an active device below the pad area is disclosed. This semiconductor structure provides an efficient use of wafer area with the device under the pad. In one embodiment, a semiconductor structure has a pad area and has an active device of the semiconductor structure disposed beneath the pad area. By incorporating a device beneath the pad area, an embodiment of the present invention improves efficiency of the use of silicon area. Fabrication of semiconductor structures according to an embodiment of the present invention provides economic benefits concomitant with improved yield of individual dies available from a wafer.

### Exemplary Structures

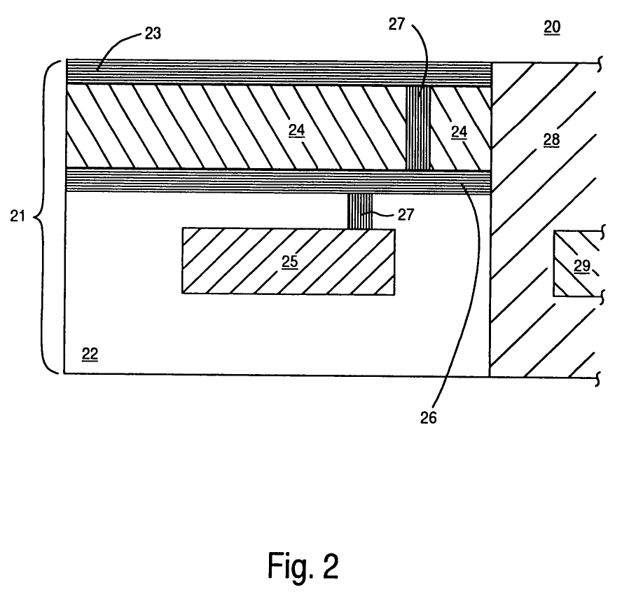

FIG. 2 depicts a cross section of a semiconductor structure 20, according to one embodiment of the present invention. Semiconductor structure 20 has a pad area 21 bordering a non-pad area 28. Non-pad area 28 is bounded, at least in part, by pad area 21. Semiconductor structure 20 has an active device 25 disposed beneath pad area 21. Active device 25 can be, for instance, a transistor. Active device 25 can be one of several components of semiconductor structure 20. For instance, another device 29 can be disposed within the non-pad area 28. In one embodiment, devices 25 and 29 perform a similar function.

The pad area 21 includes a substrate 22. Substrate 22 has a first layer of metal 26, which is disposed above it. Substrate 22 also has a second layer of metal 23, which is disposed above the first layer of metal 23. The active device 25 is disposed below the first layer of metal 26. In one embodiment, the semiconductor structure 20 also has a layer of dielectric 24, which is disposed between first metal layer 23 and second metal layer 26. In one embodiment, a via 27 is disposed within the dielectric layer 24. Via 27 electrically couples the first metal layer 23 and second metal layer 26. In one embodiment, a via 27 connects to the active device. Subsequent layers of metal can also be disposed between the first metal layer 23 and the second metal layer 26.

In one embodiment, substrate 22 comprises silicon. In one embodiment, the dielectric layer 24 is an interlayer dielectric (ILD) and can comprise a material such as tetraethoxysilane (TEOS), a similar dielectric material, or another dielectric material. The metal layers 23 and 26 (and any interlying metal layers) and via 27 can comprise any conductive metal, including but not limited to copper, aluminum, gold, silver, tungsten, or any other conductive metal, or another conductive material, such as polycrystalline silicon (POLY) and tungsten silicide, among others.

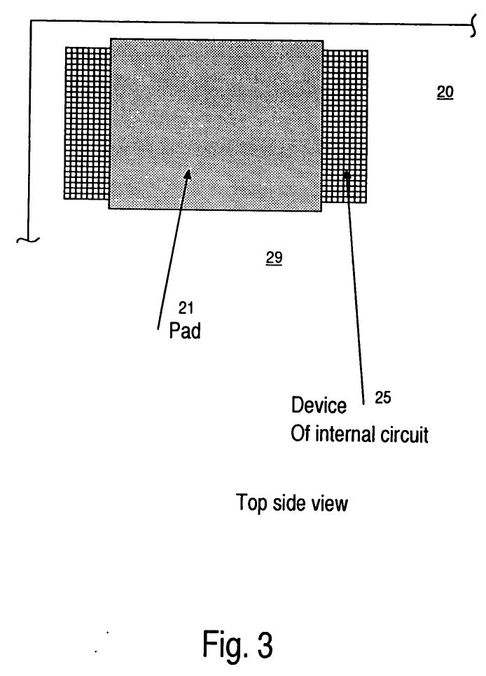

FIG. 3 depicts a top view of semiconductor structure 20 having an active device (e.g., a transistor, circuit, or the like, etc.) under the pad 21 area, according to one embodiment of the present invention. Pad area 21 bounds a portion of non-pad area 29 of semiconductor device 20. In one exemplary embodiment, semiconductor device 20 comprises a flash memory.

In such a flash memory, the pad size can be approximately 80 micrometers by 80 micrometers and the vertical size of semiconductor device 20 can be approximately 3,000 micrometers. In one exemplary implementation, 100 individual dies (e.g., individual active components) may be singulated from the non-pad area 29 of semiconductor structure 20 and three more individual active components from beneath the pad area 21. In the present implementation, this results in a three per cent increase in active devices over a semiconductor structure with no such active components located beneath its pad area.

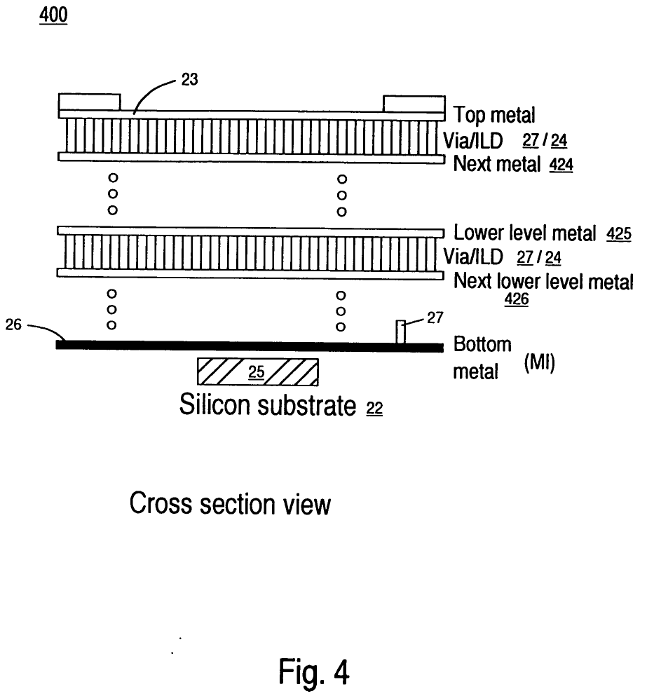

FIG. 4 depicts a cross section of a pad area 400 having an active device 25 there under, according to one embodiment of the present invention. Pad area 400 is disposed above a silicon substrate 22, wherein an active device 25 is disposed.

A top layer of metal 23 forms an upper surface of pad area 400, in one embodiment. In another embodiment, top metal layer 23 can have a layer of another material, such as a coating, oxide, etc., over it. A second metal layer 424 is disposed below top metal layer 23. An interlayer dielectric (ILD) 24 is disposed between top metal layer 23 and second metal layer 424. Top metal layer 23 and second metal layer 424 are electrically interconnected by via 27, which in one embodiment comprises a plurality of individual vias.

Below second metal layer 424, a third metal layer 425 is disposed. A fourth metal layer 426 is disposed below third metal layer 426. An interlayer dielectric (ILD) 24 is disposed between third metal layer 425 and fourth metal layer 426. Third metal layer 425 and fourth metal layer 426 are electrically interconnected by via 27, which in one embodiment comprises a plurality of individual vias. A via 27 can electrically couple third layer of metal 425 and second layer of metal 424.

A bottom metal (M1) layer 26 is disposed over silicon substrate 22, and below fourth metal layer 426. In one embodiment, any number of additional metal layers can be disposed above bottom metal layer 26 and below fourth metal layer 426. An interlayer dielectric (ILD) 24 can be disposed between each of the additional metal layers, between one of the additional metal layers and bottom metal layer 26 and/or fourth metal layer 426, and/or between the third metal layer 425 and second metal layer 424.

A via 27 can electrically intercouple any of the additional metal layers and/or electrically couple them to any other metal layer, such as to bottom metal layer 26, or to fourth metal layer 426. A via 27 can electrically couple bottom metal layer 26 with any of the metal layers disposed above it. A via 27 can electrically couple active device 25 with any metal layer, such as bottom metal layer 26 or any metal layer disposed above it.

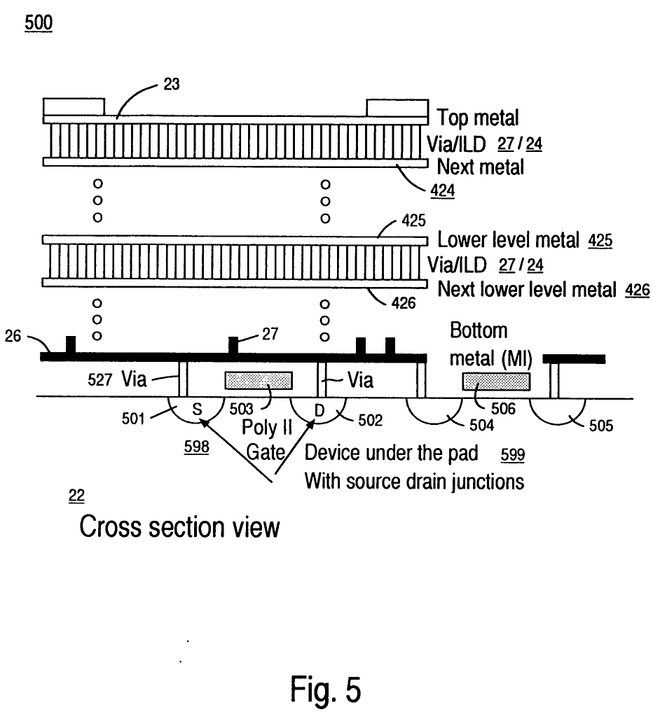

FIG. 5 depicts a cross section of a pad area 500 having as active devices there under two transistors 598 and 599, according to one embodiment of the present invention. Transistors 598 and 599 are disposed within a silicon substrate 22 beneath pad area 500. Pad area 500 has a bottom (M1) layer of metal 26 disposed above substrate 22.

Transistor 598 comprises a source region 501 and a drain region 502, disposed within appropriately doped areas of substrate 22. Source region 501 and drain region 502 are each electrically coupled to bottom metal layer 26 (or to another metal layer) by an individual via 527. Transistor 598 also comprises a gate 503, which can be of a polycrystalline silicon II (POLY-II) or another gate material disposed above and between source region 501 and gate region 502, and beneath bottom metal layer 26.

Transistor 599 comprises a source region 504 and a drain region 505, disposed within appropriately doped areas of substrate 22. Source region 504 and drain region 505 are each electrically coupled to bottom metal layer 26 (or to another metal layer) by an individual via 527. Transistor 599 also comprises a gate 506, which can be of a POLY-II or another gate material disposed above and between source region 504 and gate region 505, and beneath bottom metal layer 26.

In one embodiment, a top layer of metal 23 forms an upper surface of pad area 500. A second metal layer 424 is disposed below top metal layer 23. An interlayer dielectric (ILD) 24 is disposed between top metal layer 23 and second metal layer 424. Top metal layer 23 and second metal layer 424 are electrically interconnected by via 27, which in one embodiment comprises a plurality of individual vias.

Below second metal layer 424, a third metal layer 425 is disposed. A fourth metal layer 426 is disposed below third metal layer 426. An interlayer dielectric (ILD) 24 is disposed between third metal layer 425 and fourth metal layer 426. Third metal layer 425 and fourth metal layer 426 are electrically interconnected by via 27, which in one embodiment comprises a plurality of individual vias. A via 27 can electrically couple third layer of metal 425 and second layer of metal 424.

A bottom metal (M1) layer 26 is disposed over silicon substrate 22, and below fourth metal layer 426. In one embodiment, any number of additional metal layers can be disposed above bottom metal layer 26 and below fourth metal layer 426. An interlayer dielectric (ILD) 24 can be disposed between each of the additional metal layers, between one of the additional metal layers and bottom metal layer 26 and/or fourth metal layer 426, and/or between the third metal layer 425 and second metal layer 424. A via 27 can electrically intercouple any of the additional metal layers and/or electrically couple them to any other metal layer, such as to bottom metal layer 26, or to fourth metal layer 426. A via 27 can electrically couple bottom metal layer 26 with any of the metal layers disposed above it.

### Exemplary Processes

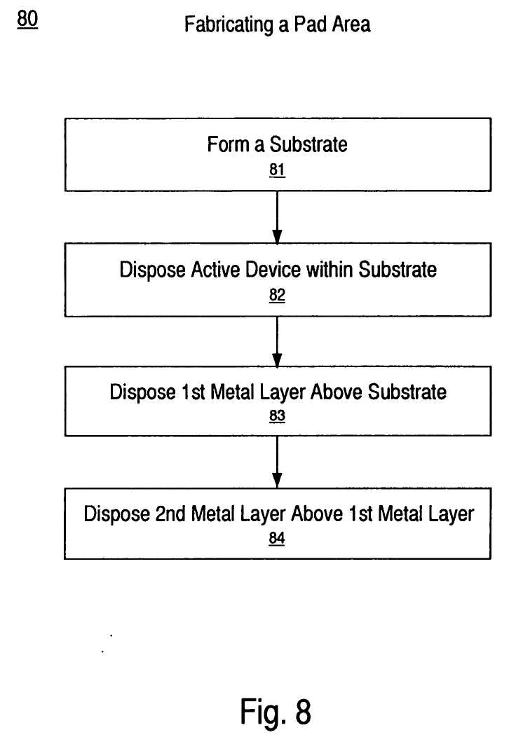

The methods described below explain processes for fabricating a semiconductor structure and a pad area for a semiconductor structure. These processes can be implemented using techniques that are well known in the art, and which are not described herein in detail, so as not to unnecessarily obscure features of an embodiment of the present invention. For example, step 81 of process 80 (FIG. 8) comprises forming a substrate. Formation of a substrate is well known in the art, and any applicable technique may be used to accomplish step 81. Any such known techniques can be applied as appropriate so as to practice an embodiment of the present invention.

Further, the processes described below are discussed for simplicity and brevity in terms of individual steps, listed in an exemplary sequence. Although specific steps and sequence thereof are disclosed in the figures discussed herein (e.g., FIGS. 6-10) describing the operations of these processes (e.g., processes 60, 70, 80, 90, and 100), such steps and sequences are exemplary. Embodiments of the present invention are well suited to performing various other steps or variations of the steps recited in the flowcharts of the figures herein, and in a sequence other than the sequence depicted and described herein.

Exemplary Processes for Fabricating a Semiconductor Structure

FIG. 6 is a flowchart of a method 60 for fabricating a semiconductor structure, according to one embodiment of the present invention. Process 60 begins with a step 61, wherein a pad area is provided. In step 62, an active device, such as a transistor for example, is disposed beneath the pad area, completing process 60.

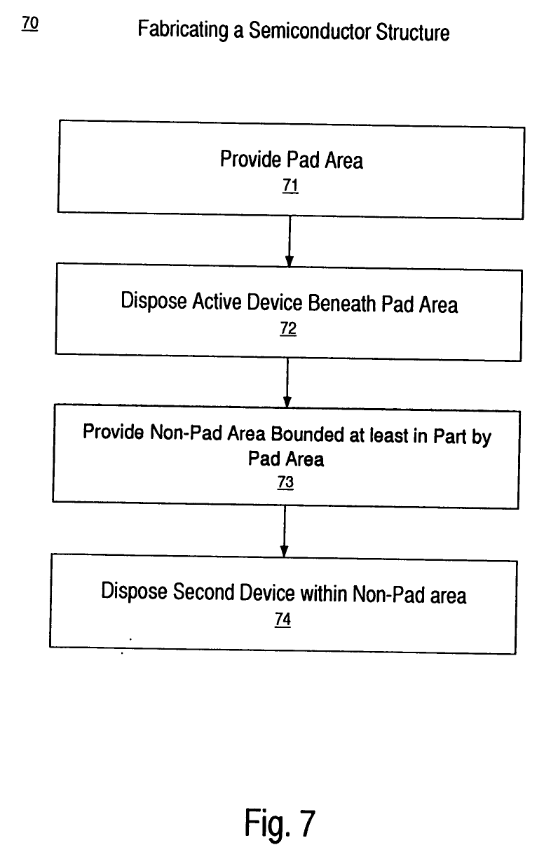

FIG. 7 is a flowchart of a method 70 for fabricating a semiconductor structure, according to one embodiment of the present invention. Process 70 begins with a step 71, wherein a pad area is provided. In step 72, an active device is disposed beneath the pad area.

In step 73, a non-pad area is provided, such that the non-pad area is bounded at least in part by the pad area. In step 74, a second component (e.g., and active device, circuit, etc.) is disposed within the non-pad area, completing process 70.

Exemplary Processes for Fabricating a Pad Area for a Semiconductor Structure

FIG. 8 is a flowchart of a method 80 for fabricating a pad area for a semiconductor structure, according to one embodiment of the present invention. Process 80 begins with step 81, wherein a substrate is formed. In step 82, an active device such as a transistor is disposed within the substrate.

In step 83, a first layer of metal is disposed above the substrate. The second metal layer, in one embodiment, comprises a bottom (M1) metal layer disposed over the substrate. In step 84, a second metal layer is disposed above the first metal layer, completing process 80.

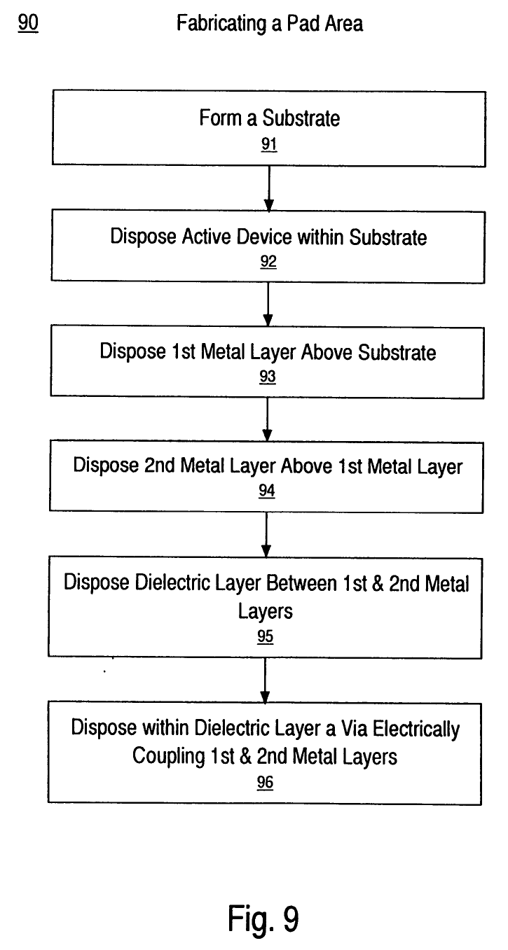

FIG. 9 is a flowchart of a method 90 for fabricating a pad area for a semiconductor structure, according to one embodiment of the present invention. Process 90 begins with step 91, wherein a substrate is formed. In step 92, an active device such as a transistor is disposed within the substrate.

In step 93, a first layer of metal is disposed above the substrate. The first metal layer, in one embodiment, comprises a bottom (M1) metal layer disposed over the substrate. In step 94, a second metal layer is disposed above the first metal layer.

In step 95, a dielectric layer such as an interlayer dielectric (ILD) is disposed between the first and second metal layers. In step 96, a via is disposed within the dielectric layer so as to electrically couple the first and second metal layers. In step 97, a via is disposed within the substrate and below the second metal layer, so as to electrically couple the active component to a metal layer, completing process 90.

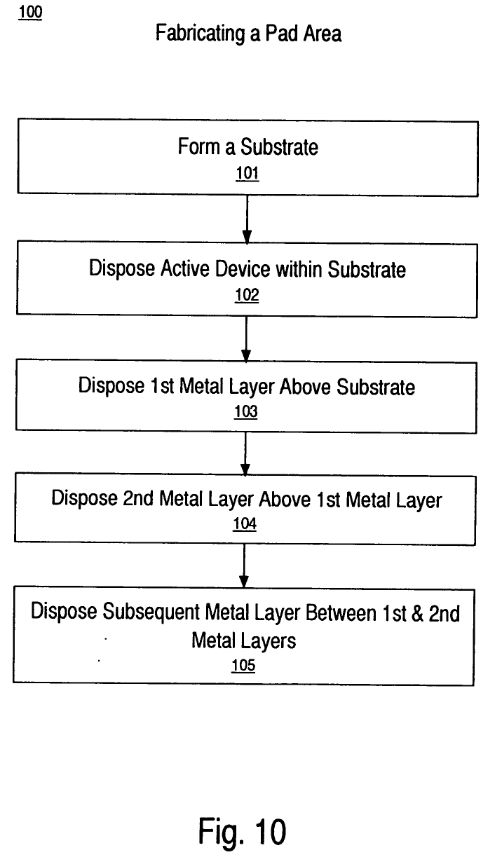

FIG. 10 is a flowchart of a method 100 for fabricating a pad area for a semiconductor device, according to one embodiment of the present invention. Process 100 begins with step 101, wherein a substrate is formed. In step 102, an active device such as a transistor is disposed within the substrate.

In step 103, a first layer of metal is disposed above the substrate. The first metal layer, in one embodiment, comprises a bottom (M1) metal layer disposed over the substrate. In step 104, a second metal layer is disposed above the first metal layer.

In step 105, a subsequent metal layer is disposed between the first and second metal layers, in one embodiment, completing process 100. In another embodiment, dielectric layers can be disposed so as to electrically separate metal layers. In yet another embodiment, a via can be disposed within the dielectric so as to electrically couple metal layers one to another and/or to the active device.

An embodiment of the present invention, a more efficient use of wafer area with a device under the pad, is thus described. While the present invention has been described in particular embodiments, it should be appreciated that the present invention should not be construed as limited by such embodiments, but rather construed according to the following claims.

1. A semiconductor structure comprising:
a pad area; and
an active device of said semiconductor structure disposed below said pad area.

2. The semiconductor structure as recited in claim 1 wherein said active component comprises a transistor.

3. The semiconductor structure as recited in claim 1 wherein a component of said semiconductor structure performs a logic function.

4. The semiconductor structure as recited in claim 1 wherein a component of said semiconductor structure performs a memory function.

5. The semiconductor structure as recited in claim 1 wherein said active device comprises a first device, said semiconductor structure further comprising:
a non-pad area bounded at least in part by said pad area; and
a second device disposed within said non-pad area.

6. The semiconductor structure as recited in claim 5 wherein said first and said second devices perform a similar function.

7. The semiconductor structure as recited in claim 1 wherein said pad area comprises:
a substrate;
a first layer of metal disposed above said substrate wherein said active device is disposed below said first layer of metal;
a second layer of metal disposed above said first layer of metal.

8. The semiconductor structure as recited in claim 7 further comprising:
a layer of dielectric disposed between said first metal layer and said second metal layer; and
a via disposed within said dielectric layer wherein said via electrically couples said first and said second metal layer.

9. The semiconductor structure as recited in claim 7 further comprising a subsequent layer of metal between said first and said second metal layers.

10. A pad area apparatus for a semiconductor structure comprising:
a substrate;
a first layer of metal disposed above said substrate;
a second layer of metal disposed above said first layer of metal; and
an active component wherein said active component is disposed within said substrate.

11. The pad area apparatus as recited in claim 10 further comprising:
a layer of dielectric disposed between said first metal layer and said second metal layer; and
a via disposed within said dielectric layer wherein said via electrically couples said first and said second metal layer.

12. The pad area apparatus as recited in claim 10 further comprising a subsequent layer of metal between said first and said second metal layers.

13-21. (canceled)
